(19) United States
(12) Patent Application Publication
(10) Pub. No.: US 2023/0318638 A1
(43) Pub. Date: Oct. 5, 2023

(54) EQUALIZATION OF DIGITAL PRE-DISTORTION SIGNAL

(71) Applicant: SEMICONDUCTOR COMPONENTS INDUSTRIES, LLC, Phoenix, AZ (US)

(72) Inventors: Abhishek Kumar AGRAWAL, Bellevue, WA (US); Reza HOSHYAR, San Jose, CA (US); Kapil GULATI, Sunnyvale, CA (US)

(73) Assignee: SEMICONDUCTOR COMPONENTS INDUSTRIES, LLC, Phoenix, AZ (US)

(21) Appl. No.: 17/710,500

(22) Filed: Mar. 31, 2022

(51) Int. Cl. H04B 1/04; H04L 25/03; H03F 1/32; H03F 3/24

(52) U.S. Cl. CPC H04B 1/0475; H04L 25/03343; H03F 1/3241; H03F 3/245; H04B 2001/0416; H03F 2200/451

(57) ABSTRACT

Methods and systems may include performing pre-equalization of a signal for transmission, where the pre-equalization includes amplifying a non-linear portion of the signal based on a frequency response of a transmit filter for the non-linear portion of the signal. In such a method or system, the non-linear portion may be configured to counteract spectral spread caused by a power amplifier, and the amplifying of the pre-equalization may cause the non-linear portion of the signal to survive filtering by the transmit filter such that the non-linear portion of the signal arrives at the power amplifier to counteract the spectral spread of the signal for transmission caused by the power amplifier.

### FIELD

The implementations discussed herein are related to pre-equalization of a digital signal for transmission.

### BACKGROUND

Unless otherwise indicated herein, the materials described herein are not prior art to the claims in the present application and are not admitted to be prior art by inclusion in this section.

Home, office, stadium, and outdoor networks, a.k.a. wireless local area networks (WLAN) are established using a device called a Wireless Access Point (WAP). The WAP may include a router. The WAP wirelessly couples all the devices of the local network, e.g., wireless stations such as: computers, printers, televisions, digital video (DVD) players, security cameras and smoke detectors to one another and to the Cable or Subscriber Line through which Internet, video, and television is delivered to the local network. Most WAPs implement the IEEE 802.11 standard which is a contention-based standard for handling communications among multiple competing devices for a shared wireless communication medium on a selected one of a plurality of communication channels. The frequency range of each communication channel is specified in the corresponding one of the IEEE 802.11 protocols being implemented, e.g., “a”, “b”, “g”, “n”, “ac”, “ad”, “ax”, “ay”, “be”. Communications follow a hub and spoke model with a WAP at the hub and the spokes corresponding to the wireless links to each ‘client’ device or station (STA) utilizing the WLAN.

Communications on the single communication medium are identified as “simplex” meaning, one communication stream from a single source node to one or more target nodes at one time, with all remaining nodes capable of “listening” to the subject transmission. Starting with the IEEE 802.11ac standard and specifically ‘Wave 2’ thereof, discrete communications to more than one target node at the same time may take place using what is called Multi-User (MU) multiple-input multiple-output (MIMO) capability of the WAP. MU capabilities were added to the standard to enable the WAP to communicate with single antenna single stream or multiple-antenna multi-stream transceivers concurrently, thereby increasing the time available for discrete MIMO video links to wireless HDTVs, computers, tablets, and other high throughput wireless devices the communication capabilities of which rival those of the WAP. The IEEE 802.11ax standard integrates orthogonal frequency division multiple access (OFDMA) into the WAP or stations capabilities. OFDMA allows a WAP to communicate concurrently on a downlink with multiple stations, on discrete frequency ranges, identified as resource units (RUs).

When communicating wirelessly, the transmitting device often will use a power amplifier to increase the radio signal being sent to the receiving device. The power amplifier is typically an analog component that, at high levels of transmission power, behaves non-linearly and degrades quality of the transmitted signal. Such non-linear behavior may degrade performance by increasing an error vector magnitude (EVM), indicating a decrease in the in-band quality of the signal. Additionally or alternatively, the non-linear behavior may result in spectral regrowth, resulting in spread of the spectrum of the signal which may leak into other frequency bands than that in which the signal is transmitted. Some entities have identified spectral masks to identify limitations on permitted bands of frequency within which signal is permitted to be broadcast, such as the Federal Communications Commission (FCC), the Institute of Electrical and Electronics Engineers (IEEE), the Body of European Regulators for Electronic Communications (BEREC), or others.

One approach to offset the non-linear effects of the power amplifier is the use of digital pre-distortion (DPD). DPD may apply controlled distortions on the digital signal before being converted to analog and then up-converted to a radio signal for transmission. The DPD may take various forms and the adopted form is often associated with the non-linearity of the power amplifier.

The subject matter claimed herein is not limited to implementations that solve any disadvantages or that operate only in environments such as those described above. Rather, this background is only provided to illustrate one example technology area where some implementations described herein may be practiced.

### SUMMARY

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter.

Some example implementations described herein generally relate to performing pre-equalization of a signal in conjunction with digital pre-distortion (DPD) to counteract non-linear aspects of a power amplifier used in transmitting a signal through a network. Some implementations provide a method, system, and/or apparatus to facilitate the application of the pre-equalization to increase the range, robustness, and/or reliability within the network.

One or more implementations may include an example method or system that includes performing pre-equalization of a signal for transmission, where the pre-equalization includes amplifying a non-linear portion of the signal based on a frequency response of a transmit filter for the non-linear portion of the signal. In such a method or system, the non-linear portion may be configured to counteract spectral spread caused by a power amplifier, and the amplifying of the pre-equalization may cause the non-linear portion of the signal to survive filtering by the transmit filter such that the non-linear portion of the signal arrives at the power amplifier to counteract the spectral spread of the signal for transmission caused by the power amplifier.

The present disclosure may be implemented in hardware, firmware, or software. Associated devices and circuits are also claimed. Additional features and advantages of the present disclosure will be set forth in the description which follows, and in part will be obvious from the present disclosure or may be learned by the practice of the present disclosure. The features and advantages of the present disclosure may be realized and obtained by means of the instruments and combinations particularly pointed out in the appended claims. These and other features of the present disclosure will become more fully apparent from the following description and appended claims or may be learned by the practice of the present disclosure as set forth hereinafter.

### BRIEF DESCRIPTION OF THE DRAWINGS

Example implementations will be described and explained with additional specificity and detail through the use of the accompanying drawings in which:

FIG. 1A illustrates an example system in the context of training DPD, described according to at least one implementation of the present disclosure.

FIG. 1B illustrates an example system in the context of utilizing DPD, described according to at least one implementation of the present disclosure.

FIG. 1C illustrates an example system in the context of utilizing pre-equalization in conjunction with DPD, described according to at least one implementation of the present disclosure.

FIG. 2 illustrates an example system of components for utilizing pre-equalization, described according to at least one implementation of the present disclosure.

FIG. 3 illustrates an example graph of a transmit filter response, pre-equalization, and a resulting signal, described according to at least one implementation of the present disclosure.

FIG. 4 illustrate an example plot of an output of DPD, described according to at least one implementation of the present disclosure.

FIG. 5 illustrates an example plot of an output of a digital to analog converter (DAC) utilizing pre-equalization and not utilizing pre-equalization, described according to at least one implementation of the present disclosure.

FIG. 6 illustrates an example plot of an example output of a power amplifier after utilizing pre-equalization and not utilizing pre-equalization, described according to at least one implementation of the present disclosure.

FIG. 7 illustrates an example plot of an output of a power amplifier based on various Power Amplifier characteristics and training approaches while varying mismatch between Tx Filter which pre-EQ is tuned to and realized variations of Tx filter due to analog circuit variations, described according to at least one implementation of the present disclosure.

FIG. 8 illustrates an example plot of an output of a power amplifier based on various Power Amplifier characteristics and training approaches while varying an order of a filter implementing the pre-equalization, described according to at least one implementation of the present disclosure.

FIG. 9 illustrates an example plot of an output of a power amplifier based on various Power Amplifier characteristics and training approaches while varying tuning of the pre-equalization, described according to at least one implementation of the present disclosure.

FIG. 10 illustrates a flowchart of an example method of transmitting a signal utilizing pre-equalization, described according to at least one implementation of the present disclosure.

FIG. 11 illustrates a flowchart of an example method of implementing pre-equalization, described according to at least one implementation of the present disclosure.

FIG. 12 illustrates a flowchart of an example method 1200 of training a system utilizing pre-equalization, described according to at least one implementation of the present disclosure.

FIG. 13 illustrates a diagrammatic representation of a machine in the example form of a computing device described according to at least one implementation of the present disclosure.

### DETAILED DESCRIPTION OF SOME EXAMPLE IMPLEMENTATIONS

When communicating between devices, there is often various filtering and signal processing which occurs. To control the adverse effect of power amplifier (PA) non-linearity, the information signal may undergo digital pre-distortion (DPD) or otherwise have intentional distortion introduced into the signal to facilitate counteracting non-linear effects of the operation of the PA associated with transmission of the signal. However, other filters, such as analog transmission filters that act on the signal between the DPD and the power amplifier, may inadvertently remove some spectral portions of the DPD signal. For example, low-pass filtering will remove high spectral components of the DPD signal, as the DPD often includes a much wider spectral occupancy than the original signal. The removal of some or all of the DPD signal by such filters may result in the power amplified signal still causing the negative effects on the signal that the DPD was intended to counteract, such as experiencing spectral spread into undesirable frequencies, such as those prescribed by regulatory bodies such as the FCC, the IEEE, the BEREC, or others. Additionally, the non-linearity of the PA may result in a degradation in the in-band signal quality as well (e.g., the EMV may increase).

Example implementations of the present disclosure include methods and systems which perform pre-equalization on a signal that counteracts aspects of the analog transmission filter's removal of some or all of the DPD signal, such that the DPD signal may survive the analog transmission filter and the intended distortion still be present in the signal to produce the desired effect of offsetting the non-linearity of the power amplifier. Additionally, the present disclosure may include approaches to implement, tune, and/or determine efficacy of such pre-equalization. In some implementations, the pre-equalization may facilitate the removal and/or reduction of non-linear behavior of the power amplifier.

In some implementations, the high-spectral components of the DPD-distorted signal (e.g., those portions of the DPD-intentionally distorted signal at higher frequencies) may be amplified in a corresponding amount to that with which they are reduced by the low-pass or transmit filters using pre-equalization. By doing so, the portions of the DPD-distorted signal that would have been filtered out by the low-pass filters instead are amplified a corresponding amount so that the DPD-distorted signal, when acted on by the combination of the pre-equalization and the transmit filter together, is essentially flat. Stated another way, the pre-equalization may operate to provide a boost to the portions of the DPD-distorted signal that would otherwise be filtered out by the low-pass filter or other transmit filters such that the frequency response of the pre-equalization and the frequency response of the low-pass filter or other transmit filters essentially offset each other such that the DPD-distorted signal survives the low-pass filter, even at the frequencies which would otherwise be filtered out.

By using one or more of the principles of the present disclosure to perform pre-equalization on a signal prior to transmission, network performance may be improved and/or efficiencies may be gained. For example, an increase in transmission power may be realized without spreading into frequencies that are prescribed by one or more regulatory masks, such as those promulgated by the FCC, IEEE, BEREC, etc. As another example, the signals being broadcast may be more precise and more clear, particularly at frequencies into which the spectral spread is avoided. By providing such increases in broadcast power and/or reliable connections, the network may operate more efficiently overall by potentially providing an increase in range of transmission, received signal strength, and/or other benefits.

These and other implementations of the present disclosure will be explained with reference to the accompanying figures. It is to be understood that the figures are diagrammatic and schematic representations of such example implementations, and are not limiting, nor are they necessarily drawn to scale. In the figures, features with like numbers indicate like structure and function unless described otherwise.

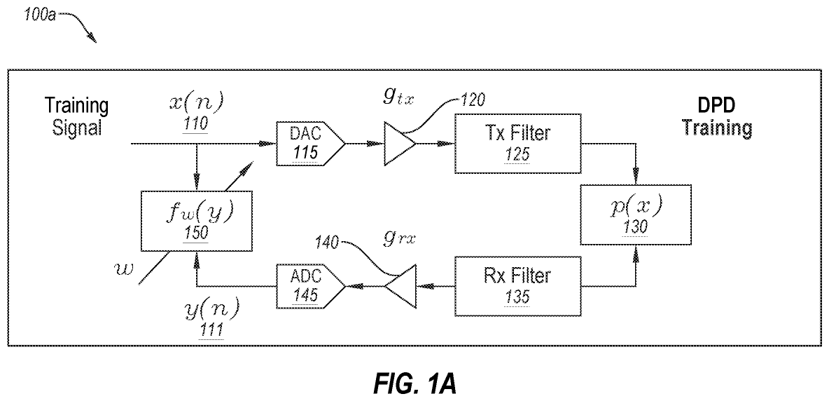

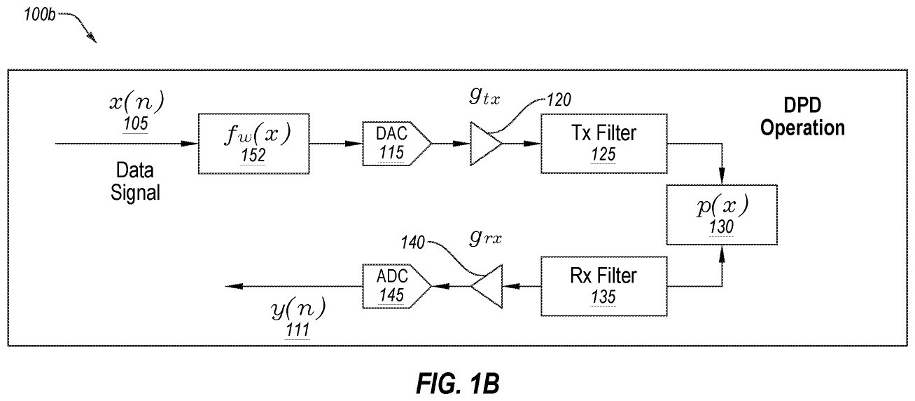

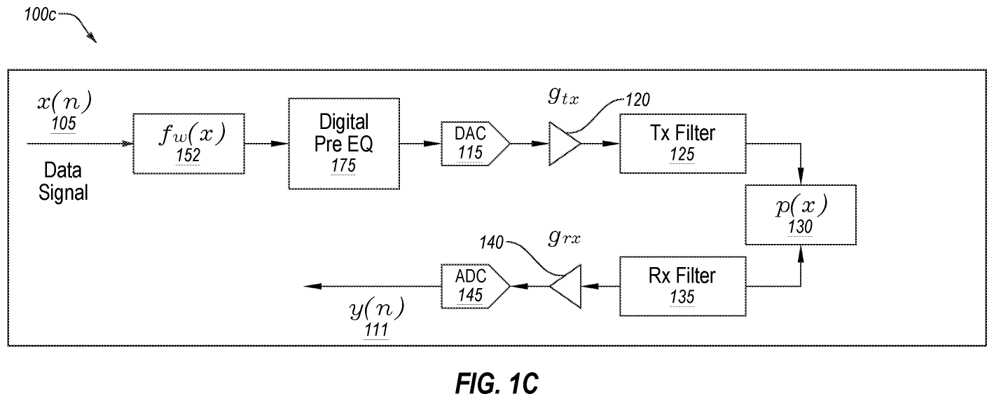

FIG. 1A-1C illustrate various example systems 100a-100c in the context of training a DPD, utilizing a DPD, and utilizing pre-equalization, according to at least one implementation of the present disclosure. For example, the system 100a may depict the training of a DPD, the system 100b may depict the use of the DPD, and the system 100c may depict the use of the DPD in conjunction with pre-equalization. In practical systems, there are other blocks utilized for proper and reliable operation of a wireless transceiver. These blocks are used, for example, to compensate for other non-idealities of a practical transmitter and receiver, such as DC offset, transmit/receive IQ imbalance, phase noise, ppm and frequency drift, LO leakage, and so on. For the convenience of description, these blocks are not included in these figures. In this regard the presented figures are just examples and do not limit the application of the present disclosure.

As illustrated in FIG. 1A, the system 100a may include a training signal 110 (identified as x(n)) that may be provided to a digital to analog converter (DAC) 115. The output of the DAC signal may go through one or more RF chain components such as analog amplification, filtering, mixing, and up conversion to RF frequency. The baseband equivalent of the collective effect of these stages is modeled as a gain element of gₜₓ and a baseband transmit (Tx) filter. As a result, in this model the DAC output signal goes through gain stage 120 (identified as gₜₓ). The signal x(n) may then be passed through a transmit filter 125, such as a low pass filter, that may filter the signal x(n) before being passed to the power amplifier 130 (identified as p(x)). The signal may then be transmitted and received.

After being received, the signal x(n) may undergo filtering at a receive filter 135 and undergo amplification at a receiving amplifier (identified as gᵣₓ) 140. In a similar manner with the transmitter, the gain and receive filter components are just a baseband equivalent model representing the overall RF processing of down-conversion from RF to baseband frequency, and relevant analog processing utilized in a practical receiver that can be captured by some form of gain and filtering. The signal may then be provided to an analog to digital converter (ADC) 145 that converts the signal y(n) 111 into a digital signal.

The system 100a may utilize a comparison of the training signal x(n) 110 before processing and transmission with the received signal y(n) 111 after processing to facilitate training of the DPD. For example, a comparator 150 may operate to determine a function ƒ_{w}(y) that converts the received signal y(n) 111 into a signal that is similar to, the same as, or has the closest similarity to the training signal x(n) 110 by modifying a coefficient or set of coefficients w. The result of the training of the DPD associated with FIG. 1A may result in the determination of the function ƒ_{w}(y) that may be the desired DPD as the DPD may counteract the signal adjustment, particularly that due to the power amplifier 130, such that the received signal corresponds to the transmitted signal. In a practical training scenario, there may be some latency from the input of the DAC 115 to the output of ADC 145. Also, the DAC 115 and ADC 145 might not have the same sampling rates. In this regard the signals x(n) and y(n) may be time-synchronized, for example, by applying some delay to the signal x(n). Additionally or alternatively, the DAC 115 and the ADC 145 may be converted to a same sampling rate by interpolation/decimation before being used in tuning of the function ƒ_{w}(y).

FIG. 1B illustrates the example system 100b in the context of utilizing DPD. For example, the system 100b may be similar to the system 100a. However, the system 100b may utilize signal processing corresponding to the determined function ƒ_{w}(y) as a digital pre-distortion (DPD) 152. When utilizing the DPD 152, a data signal 105 (identified as x(n)) may undergo similar or comparable processing and filtering as described with reference to FIG. 1A, with the addition of the DPD 152 prior to the DAC 115. By providing the DPD 152, the received signal 111 (y(n)) may be similar or comparable to the transmitted data signal 105.

In some implementations, the transmit filter 125 may filter out certain aspects of the intentional distortion introduced by the DPD 152. For example, the transmit filter 125 may operate as a low-pass filter to decrease or remove signal outside of the band for transmission, such as filtering out frequencies that are prescribed by the FCC, IEEE, etc. As another example, the transmit filter 125 may operate as a low-pass filter that reduces the magnitude of the signal at higher frequencies. In these and other implementations, the DPD 152 may intentionally introduce certain signal processing on the signal that falls in the frequency range that may be filtered out by the transmit filter 125. In such a circumstance, the transmit filter 125 may remove a desired part of the signal processing introduced by the DPD 152 to counteract non-linear aspects of the power amplifier 130, resulting in spectral spread into the prohibited or undesirable frequency domains, and signal quality degradation due to inefficient compensation of the power amplifier non-linearity.

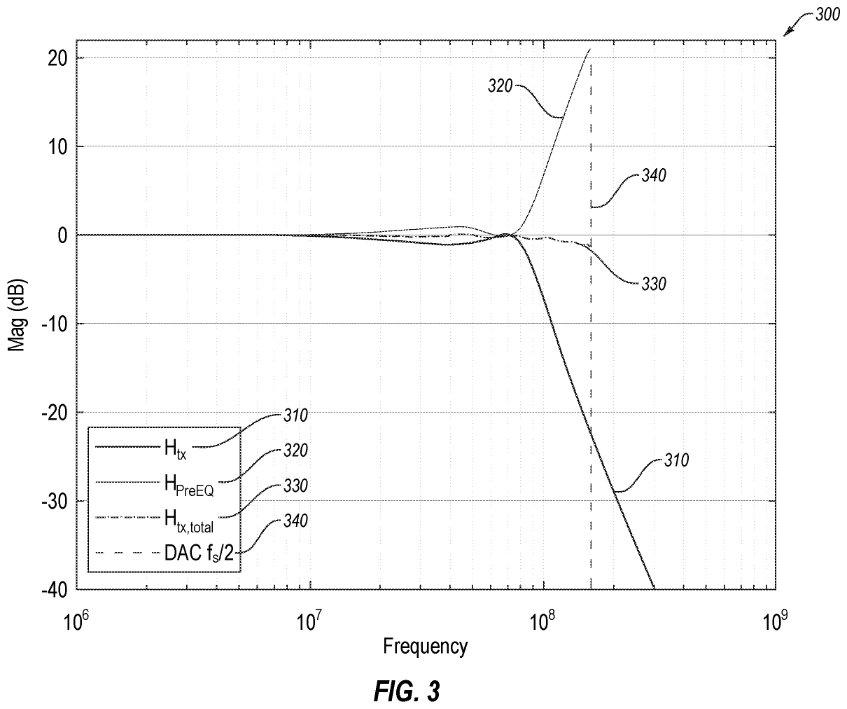

FIG. 1C illustrates the example system 100c in the context of utilizing pre-equalization in conjunction with DPD, described according to at least one implementation of the present disclosure. The system 100c may be similar or comparable to the system 100b illustrated in FIG. 1B, but with the addition of a digital pre-equalizer 175. The digital pre-equalizer 175 may be configured to amplify the aspects of the DPD 152 that are acted upon by the transmit filter 125. For example, the transmit filter 125 may operate with a frequency response that decreases the amplitude of signals at various frequencies (such as operating as a low-pass filter that decreases the amplitude of high frequencies), and the digital pre-equalizer 175 may amplify the signals in a corresponding amount to counteract the attenuation experienced by filtering of Tx Filter 125. FIG. 3 illustrates an example of the frequency response of a transmit filter and the corresponding amplification performed by the pre-equalization of the digital pre-equalizer 175.

Modifications, additions, or omissions may be made to the systems 100a-100c without departing from the scope of the present disclosure. For example, the designations of different elements in the manner described is meant to help explain concepts described herein and is not limiting. Additionally, the systems 100a-100c may be a simplified depiction of the elements used in transmission or reception of a signal, with other elements omitted for convenience in conveying the principles of the present disclosure.

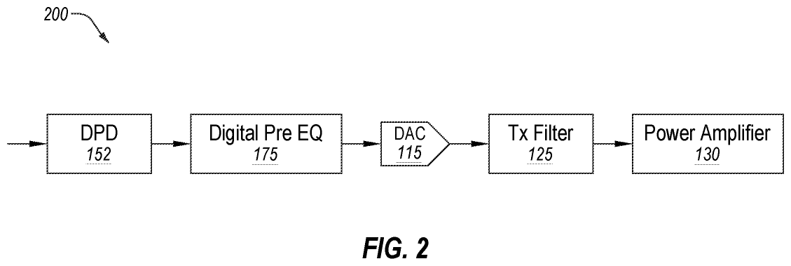

FIG. 2 illustrates an example system 200 of components for utilizing pre-equalization, described according to at least one implementation of the present disclosure. The system 200 may be similar or comparable to the system 100c of FIG. 1C, but omitting the elements related to the reception of the signal and/or used in training the DPD. For example, the system 200 may include the DPD 152, the pre-equalizer 175, the DAC, the transmit filter 125, and the power amplifier 130 as a transmit chain. In some implementations, the initial signal, the DPD 152, and the pre-equalizer 175 may operate within a digital domain, and the DAC 115 may convert the processed digital signal into the analog domain. In these and other implementations, the transmit filter 125 and the power amplifier 130 may operate in the analog domain.

In operation, the DPD 152 may be trained using a training signal as described, for example, with reference to FIG. 1A. The trained DPD 152 may introduce intentional distortions that correspond to non-linear behavior of the power amplifier 130. In some circumstances, the distortions introduced by the DPD 152 may be particularly important towards the periphery of a band of transmission (such as at high frequencies), which may also be portions of the frequency domain within which the transmit filter 125 may be more likely to filter out the distortion. For example, towards the edges of a frequency band may be the frequencies which the power amplifier 130 is unlikely to amplify in a linear manner, resulting in a potential drop in performance in form of the signal quality degradation, e.g., EVM increase, and regulatory spectral mask violations. Additionally, it is at these very frequencies that the transmit filter 125 is most likely to reduce the amplitude of the signal.

The DPD 152 may be generated and/or implemented in any of a number of approaches. For example, the DPD 152 may be polynomial based with any order, polynomial based with some memory, look up table (LUT)-based, LUT with some memory, among other approaches for implementing or generating the DPD.

After a signal is processed by the DPD 152, the distorted signal is provided to the pre-equalizer 175 to receive digital pre-equalization. The digital pre-equalization may be selected and configured to counteract any (or some) filtering or signal attenuation of the transmit filter 125 that removes some part of the desired portions of the distortion introduced by the DPD 152. While described as digital pre-equalization, it will be appreciated that the pre-equalization may be performed in the analog domain and moved to be performed at some point after the DPD 152 is introduced and before the transmit filter 125 acts on the distorted signal (such as between elements 115 and 125). For example, the pre-equalization may be performed by stages of analog components, such as resistors, capacitors, op amps, transistors, field effect transistors (FETs), among other components. In these and other implementations, the analog components of the pre-equalizer 175 may or may not be consecutive. For example, the pre-equalization process may be realized through multiple stages through the signal chain from the output of digital pre-equalization 175 to the input of Tx filter 125. Some implementations may introduce the pre-equalization at any stage after the Tx filter 125 and before the power amplifier 130. In some implementations, the analog components may be tunable based on input parameters that may adjust which analog components are utilized or excluded from use in performing the pre-equalization, or may adjust parameters of the components in use, such as modifying a variable resistor, increasing the gain of an op amp, among other adjustments.

In some implementations, the digital pre-equalization may be determined by comparing a ratio of a frequency response of the total desired signal and the frequency response of the transmit filter 125. For example, stated mathematically:

|H_{PreEQ}(ƒ)|=|H_{Total}(ƒ)|/|H_{Tx}(ƒ)|

where |H_{PreEQ}(ƒ)| may represent an absolute value of the frequency response of the pre-equalization, |H_{Total}(ƒ)| may represent an absolute value of the desired frequency response of the total signal, and |H_{Tx}(ƒ)| may represent an absolute value of the frequency response of the transmit filter 125. In these and other implementations, a target of the total response may be determined using a mathematical comparison of the frequency and the sampling rate of the frequency in a manner that is tunable using an exponent α. For example, stated mathematically:

|H_{Total}(ƒ)|=|sinc(ƒ/ƒₛ)|^{α}

$$( e . g . , \frac{sin ( x )}{x} )$$

where |sinc(ƒ/ƒₛ)| may represent an absolute value of the sinc function operating on a ratio of the frequency (ƒ) and the sampling rate of the frequency (ƒₛ). The exponent α may be a tunable exponent that may be used to slightly alter the target of the total response. For example, if the exponent α is zero, the total response is flat, and the exponent α may be shifted away from zero to tilt the total response in one direction or another to facilitate improved performance of the pre-equalizer 175. The configurable mathematical form presented for the absolute value of the total frequency response is provided as an example and one of the many ways to introduce a configurable total frequency response. Additionally, there may be more configuration parameters similar to parameter a used for configuring and controlling the shape of the total frequency response.

In some implementations, the exponent α may be tuned based on monitored performance of the pre-equalizer 175 relative to decreasing spectral spread, for example, with reference to an FCC mask or other mask.

In some implementations, the pre-equalizer 175 may be implemented via an infinite impulse response (IIR) filter or a finite impulse response (FIR) filter. In these and other implementations, aspects of the pre-equalizer may be determined, refined, and/or otherwise tuned mathematically. For example, an autoregression process may be used to determine coefficients of a filter to implement the pre-equalizer 175. For example, the autoregression process on the power spectral density of the pre-equalizer 175 may be performed, which may be stated mathematically as:

P_{PreEQ}(ƒ)=|H_{PreEQ}(ƒ)|²

where P_{PreEQ}(ƒ) may represent the power spectral density of the pre-equalizer 175. An Inverse Fast Fourier Transform (IFFT) may be used to calculate an autocorrelation function of the autoregression process, which may be stated mathematically as:

R_{PreEQ}(m)= [symbol] ⁻¹{P_{PreEQ}(ƒ)}

where R_{PreEQ} (m) may represent the autocorrelation function, and [symbol] ⁻¹ may represent the IFFT process. In these and other implementations, the coefficients of an IIR filter may be solved for using the autoregression process. For example, the Yule-Walker equations may be solved for to determine the coefficients of an IIR filter to implement the pre-equalizer 175. In these and other implementations, the order of the autoregression process may correlate to an order of the IIR filter. While one example of solving for the coefficients of the IIR filter is disclosed, any process or mathematical approach may be undertaken to determine the coefficients of the IIR filter.

In some implementations, a comparable FIR filter may be utilized. For example, the impulse response of the IIR filter may be truncated such that the comparable FIR may be determined and utilized instead of the IIR filter. In these and other implementations, the pre-equalizer 175 may be configured to offset the frequency response of the transmit filter 125 up to approximately one half of the Nyquist frequency of the pre-equalizer 175.

In some implementations, the pre-equalization may include filtering or processing that includes a gain of approximately one (e.g., the signal stays the same) for low-frequency values and increases at higher frequencies in a similar amount to that of the transmit filter 125. FIG. 3 illustrates an example of such a frequency response.

After undergoing the pre-equalization, the signal is converted to analog via the DAC 115 and filtered by the transmit filter 125. The transmit filter 125 may attenuate the signal spectrum corresponding to the non-linear portions intentionally introduced by the DPD 152 in a similar or comparable amount to that amplified by the pre-equalizer 175, which may result in a signal similar or comparable after the transmit filter 125 as that after the DPD 152. Stated another way, the combination of the transmit filter 125 and the pre-equalizer 175 may result in a signal (although analog) that is comparable to what is output from the DPD 152.

While illustrated as a single component, it will be appreciated that the transmit filter 125 may include any number of components and/or operations within a device that may result in the signal response. For example, analog components may perform base band gain and/or signal conditioning, filtering of one or more types (e.g., filtering out various bands of frequencies, a low-pass filter, a spectrally selective filter, among others), up conversion of the signal, mixing of the signal, radio frequency (RF) gain and/or signal conditioning, among others. In some implementations, the pre-equalizer 175 may offset a combination of some or all of these components in the transmit chain. In some implementations, the pre-equalizer 175 may offset only a small number (such as one) of such components, such as a low pass filter.

In some embodiments, the transmit filter 125 may provide feedback to the pre-equalizer 175. For example, the pre-equalizer 175 may receive an output of the transmit filter 125 and compare the output of the transmit filter 125 to a stored version of the output of the DPD 152 received by the pre-equalizer 175 to determine an effectiveness of the pre-equalizer 175. As another example, only certain portions (such as certain frequencies) may be provided to the pre-equalizer 175. In response to the feedback, the pre-equalizer 175 may adjust one or more operating parameters of the pre-equalizer 175 to modify or adjust operation of the pre-equalizer 175. For example, the pre-equalizer 175 may adjust the exponent α, an order of a filter, or other parameters.

After undergoing filtering by the transmit filter 125, the signal may be amplified by the power amplifier 130 for transmission. Additionally, the non-linear effects of the power amplifier 130 may be offset in whole or in part by the portion of the distortion introduced by the DPD 152 that survives the transmit filter 125 due to the amplification by the pre-equalizer 175.

In some embodiments, the power amplifier 130 may provide feedback to the pre-equalizer 175. For example, the pre-equalizer 175 may receive an output of the power amplifier 130 and compare the output of the power amplifier 130 to a stored version of the input to the DPD 152 to determine an effectiveness of the pre-equalizer 175. As another example, only certain portions (such as certain frequencies, a range of high frequencies, or other portions of the output of the power amplifier 130) may be provided to the pre-equalizer 175. In response to the feedback, the pre-equalizer 175 may adjust one or more operating parameters of the pre-equalizer 175 to modify or adjust operation of the pre-equalizer 175. For example, the pre-equalizer 175 may adjust the exponent α, an order of a filter, or other parameters.

In some implementations, the use of the pre-equalizer 175 may result in improved signal quality within a targeted spectral band, and a decrease in spectral leak into adjacent bands when amplifying the signal. By doing so, an original data rate of signal may be used, but an increased transmit power may be used because of the counteraction of the non-linear performance of the power amplifier 130 when compared to a signal transmitted without the use of the pre-equalizer 175. Additionally or alternatively, the same transmit power may be used compared to a signal transmitted without the pre-equalizer 175, but a higher data rate may be used due to improved signal quality within the target band. Additionally, in some implementations the use of the pre-equalizer 175 may allow for further increase in transmit power and at the same time result in a decrease in the EVM due to a more linear response of the power amplifier. This in turn will allow an increase in the data rate due to improved signal quality and increased communication range due to increased transmit power.

Modifications, additions, or omissions may be made to the system 200 without departing from the scope of the present disclosure. For example, the designations of different elements in the manner described is meant to help explain concepts described herein and is not limiting. Additionally, the system 200 may represent a simplified depiction of the elements used in transmission of a signal, with other elements omitted for convenience in conveying the principles of the present disclosure.

FIG. 3 illustrates an example graph 300 of a transmit filter response, pre-equalization, and a resulting signal, described according to at least one implementation of the present disclosure.

The plot 300 may include a frequency of the signal along an x-axis (in logarithmic scale) with magnitude (in dB) along the y axis. The plot 300 may include a first line 310 that depicts a frequency response of a transmit filter, a second line 320 that depicts a frequency response of a pre-equalization, and a third line 330 that depicts the total signal after the effects of both the transmit filter and the pre-equalization at various frequencies. The plot 300 may include a marker 340 indicating the half of the sampling frequency used for digital pre-equalizer and DAC.

As illustrated in FIG. 3 by observing the first line 310, the transmit filter includes minor variations in the frequency response between 1×10⁷ and 1.5×10⁷. Additionally, a significant effect is observed at approximately 1.8×10⁷ which continues such that by 1×10⁸, the signal may be reduced by approximately 10 dB and by 1.1×10⁸, the signal may be reduced by over 20 dB. In an inverse and comparable manner, the second line 320 illustrates the frequency response of the pre-equalization that essentially mirrors that of the transmit filter, such that the pre-equalization corresponding to the second line 320 may amplify the signal in an amount that offsets the reduction in amplitude caused by the transmit filter. The result of both the pre-equalization and the transmit filtering (as observed by the third line 330) may result generally in the signal at its original strength before the pre-equalization across all frequencies up to approximately the frequency cutoff 340.

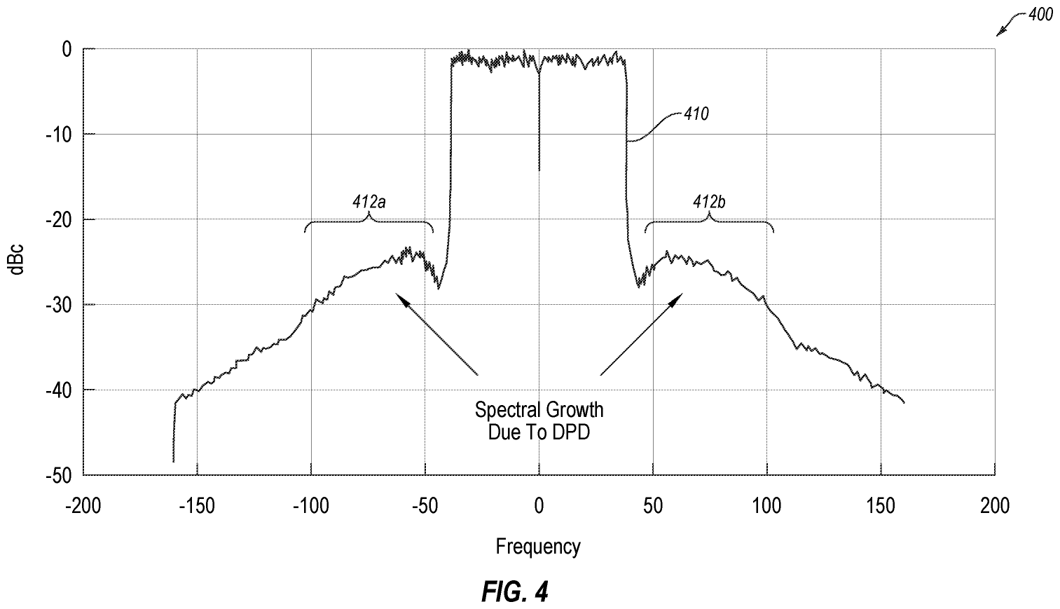

FIG. 4 illustrate an example plot 400 of an output of DPD, described according to at least one implementation of the present disclosure.

The plot 400 may include a frequency of the signal along an x-axis with magnitude (in dBc (the dB of the signal relative to the carrier) along the y axis. The plot 400 depicts a bandwidth of 80 MHz (for example, signal beyond +/−40 MHz is likely to be filtered or undesirable signal). The plot 400 may include a line 410 that depicts a frequency response of the DPD, with the maximum values in the 80 MHz window but with spectral growth 412a/412b due to the DPD just outside of the 80 MHz window. Stated another way, the DPD may introduce non-linear portions of signal processing outside of the 80 MHz window in a way to offset the effect of the power amplifier.

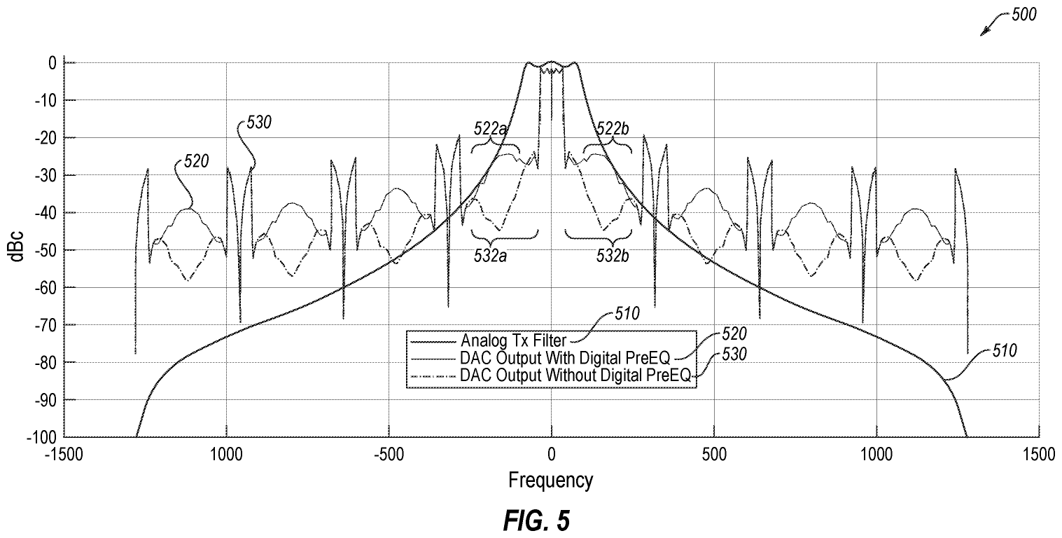

FIG. 5 illustrates an example plot 500 of an output of a digital to analog converter (DAC) utilizing pre-equalization and not utilizing pre-equalization, described according to at least one implementation of the present disclosure. For the plot 500, the DAC is using a zero-order hold, and the bandwidth of the signal for transmission is 80 MHz. The plot 500 may include a first line 510 depicting an analog transmission filter, a second line 520 depicting the output of the DAC when using pre-equalization, and a third line 530 when not using pre-equalization.

As illustrated in the plot 500, the output of the DAC 520 (with pre-equalization) and 530 (without pre-equalization) is nearly identical within the central 80 MHz band, and at periodic replicas of the DAC signal (which occur by virtue of the digital signal input to the DAC). In other regions, there is divergence between the second line 520 and the third line 530 due to the increase in the signal strength in the non-linear regions of the frequency response. For example, the spectral growth 522a and 522b of the DPD on the second line 520 is significantly amplified due to the pre-equalization, while the same regions of spectral growth due to DPD 532a and 532b of the third line 530 are left as they were at the output of the DPD.

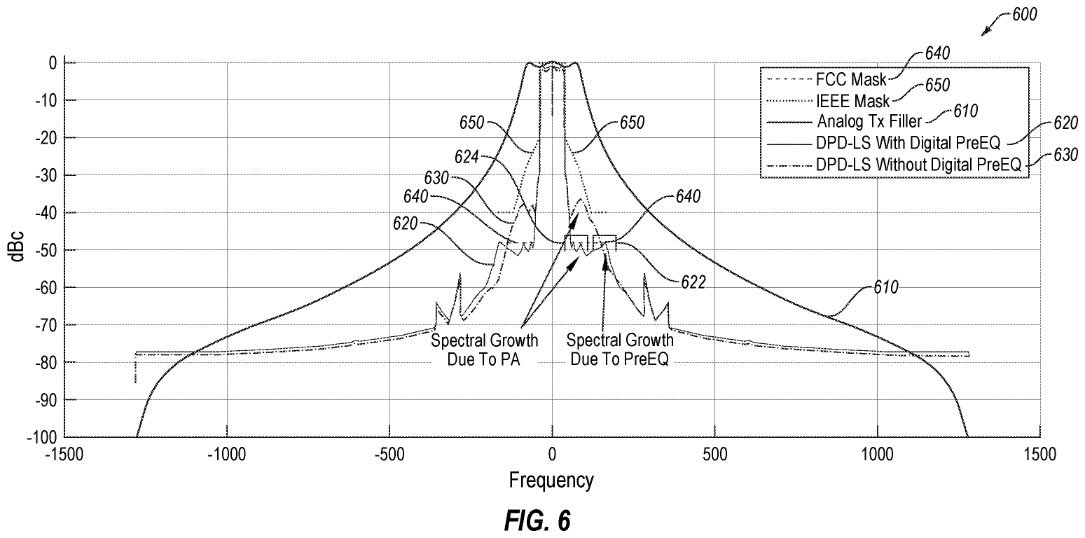

FIG. 6 illustrates an example plot 600 of an example output of a power amplifier after utilizing pre-equalization and not utilizing pre-equalization, described according to at least one implementation of the present disclosure. For the plot 600, the transmit power is 21 dBm at a bandwidth of 80 MHz, and a crest factor reduction (CFR) level of 4 dB is used. The plot 600 may include a first line 610 depicting an analog transmission filter, a second line 620 depicting the output of the power amplifier when using pre-equalization, and a third line 630 when not using pre-equalization. The plot 600 also may include an FCC mask 640 and an IEEE mask 650.

With reference to the second line 620 of the output when using pre-equalization, a first region of spectral growth 622 may stay below the FCC mask 640. A first region of the spectral growth 624 may result in maintaining the output of the power amplifier below the FCC mask 640 in the second region 624. With reference to the third line 630, the output of the power amplifier may extend well beyond the FCC mask 640, while remaining below the IEEE mask 650.

When observing the spectral growth due to DPD illustrated in FIG. 4, it is observed how that growth is diminished in FIG. 5 without the pre-equalization, which results in an increase in output of the power amplifier and violation of the FCC mask as observed in FIG. 6 in the regions prescribed by the FCC mask 640. In contrast, the use of the pre-equalization amplifies the spectral growth of the DPD to overcome the effect of the transmit filter such that in the output of the power amplifier observed in FIG. 6, the signal remains below the FCC mask 640.

As illustrated by the first and second regions 622 and 624 of the second line 620, there is a balance between increasing the spectral growth of the DPD so much that it extends up but not above the FCC mask 640 in the first region 622 and the spectral boost of the pre-equalization resulting in the second region 624 extending approximately up to, but not above the FCC mask 640.

While the FCC mask 640 and the IEEE mask 650 are used to facilitate depicting aspects of the present disclosure, any metric or cutoff may be used to identify the boundaries below which unwanted signal may be expected to be. Additionally, the FCC mask 640 simply serves as a visual indication of the performance of the pre-equalization to facilitate description of implementations of the present disclosure.

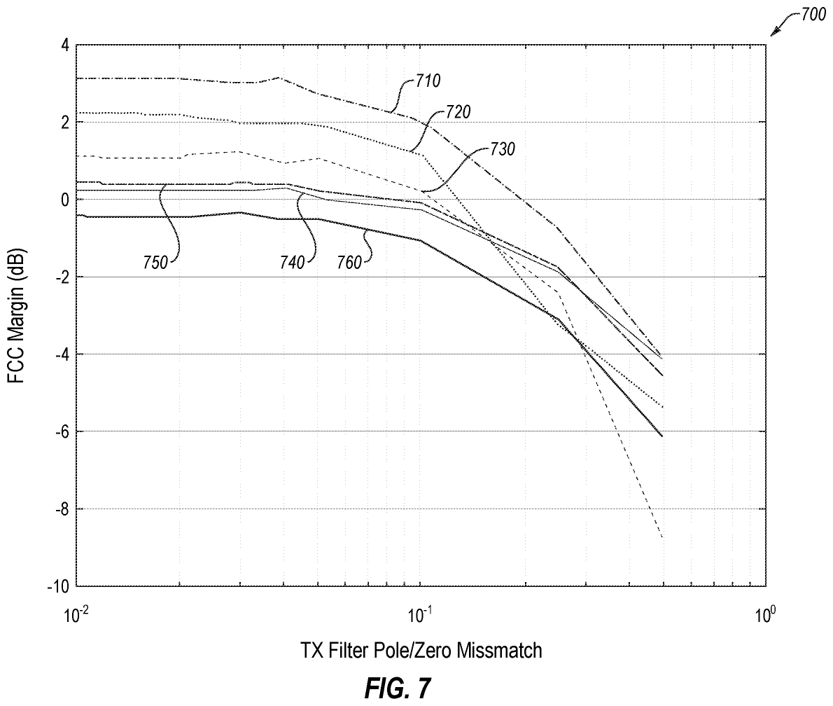

FIG. 7 illustrates an example plot 700 of an output of a power amplifier based on various power amplifier non-linearities and training approaches while varying mismatch between various filters, described according to at least one implementation of the present disclosure. For the plot 700, the degree of miss-match between the realized response of the transmit filter and the nominal response of the transmit filter which the pre-equalization is tuned for is illustrated along the x-axis (e.g., with 10⁻¹ representing a 10% difference in parameters (poles and zeros) of the randomly many realized transmit filters versus the nominal parameter values of the transmit filter), and the FCC margin in dB along the y-axis (e.g., a more positive value indicating favorable performance relative to the FCC margin and a more negative value representing poor performance relative to the FCC margin). The plot 700 may include a series of lines representing a combination of training signal for training the DPD and power amplifier at a commonly tuned pre-equalization. A first line 710 may depict a combination of a first type of training sequence and a 7.1 GHz power amplifier, a second line 720 may depict a combination of the first type of training sequence and a 5.9 GHz power amplifier, a third line 730 may depict a combination of the first type of training sequence and a 5.1 GHz power amplifier, a fourth line 740 may depict a combination of a second type of training sequence, and the 5.1 GHz power amplifier, a fifth line 750 may depict a combination of the second type of training sequence and the 5.9 GHz power amplifier, and a sixth line 760 may depict a combination of the second type of training sequence and the 7.1 GHz power amplifier.

As observed by the plot 700, all of the pre-equalizations maintained an adequate level relative to the FCC mask through various differences in the transmit filter operation and configuration up to approximately 10% variation in the transmit filter. Beyond the 10% variation, the performance of the pre-equalization deteriorated significantly. Stated another way, for tuning and monitoring the pre-equalization, the pre-equalization is effective across variations in transmit filter to a certain extent (e.g., up to 10% variation in the transmit filter parameters).

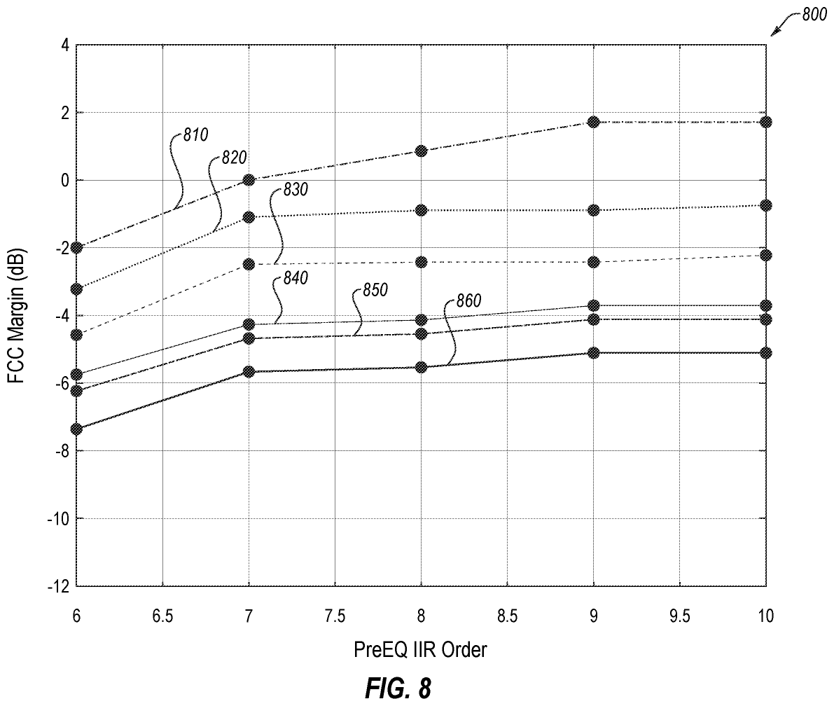

FIG. 8 illustrates an example plot 800 of an output of a power amplifier based on various power amplifier non-linearities and training approaches while varying order and/or complexity of various pre-equalization filters, described according to at least one implementation of the present disclosure. For the plot 800, the order of an IIR filter implementing the pre-equalization is varied between 6 and 10 along the x-axis, and the FCC margin in dB along the y-axis (e.g., a more positive value indicating favorable performance relative to the FCC margin and a more negative value representing poor performance relative to the FCC margin). The plot 800 may include a series of lines representing a combination of training signal and power amplifier at a given tuning of the pre-equalization. Lines 810, 820, 830, 840, 850, and 860 may include similar training and power amplification as the lines 710, 720, 730, 740, 750, and 760, respectively.

As observed by the plot 800, as the order of the IIR filter increases, the performance of the pre-equalization improves, however for some training/power amplification combinations, there is minimal difference between an order of 7 and 10, while certain combinations may obtain additional benefit for the higher order IIRs for implementing the pre-equalization. For example, the line 810 continues to increase performance at increased order until an order of 9, while the lines 840, 850, and 860 experience minor gains when increasing from order 8 to order 9. Stated another way, as the order of the IIR increases, the performance increases but to a point of diminishing returns and at a cost of increased complexity in the pre-equalization.

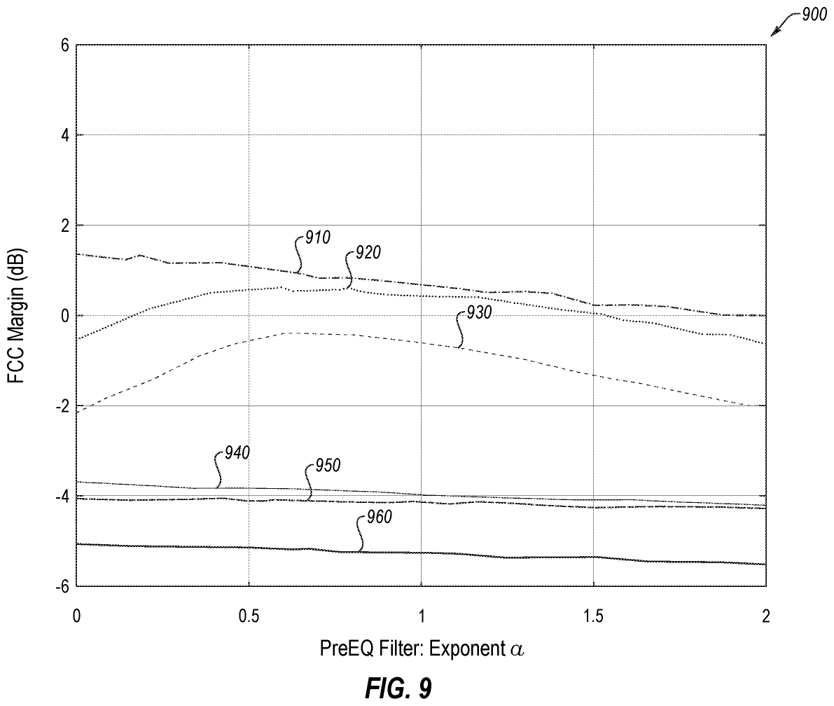

FIG. 9 illustrates an example plot 900 of an output of a power amplifier based on various power amplifier non-linearities and training approaches while varying tuning of the pre-equalization, described according to at least one implementation of the present disclosure. For the plot 900, an exponent α used in tuning the pre-equalization is varied between 0 and 2 along the x-axis, and the FCC margin in dB along the y-axis (e.g., a more positive value indicating favorable performance relative to the FCC margin and a more negative value representing poor performance relative to the FCC margin). The plot 900 may include a series of lines representing a combination of training signal and power amplifier at a given tuning of the pre-equalization. Lines 910, 920, 930, 940, 950, and 960 may include similar training and power amplification as the lines 710, 720, 730, 740, 750, and 760, respectively.

As observed by the plot 900, for the lines 940, 950, and 960, variation in the exponent α has little effect on the performance of the pre-equalization. For the line 910, as the exponent α increases, the performance decreases slightly. For the lines 920 and 930, the performance increases with an increase in the exponent α up to about 0.6, and then decreases as the exponent α increases. In some implementations, the value of the exponent α may be tuned and monitored as illustrated in the plot 900 to determine experimentally a value for α to be used for a given combination of training signal and power amplifier non-linearity.

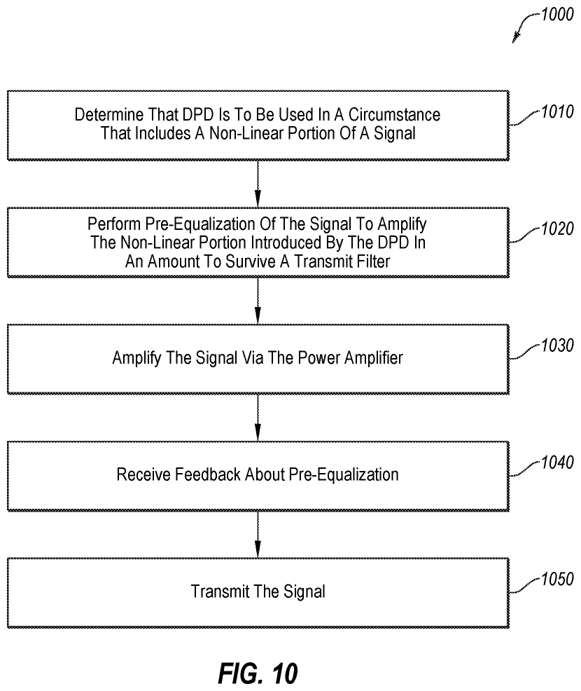

FIG. 10 illustrates a flowchart of an example method 1000 of transmitting a signal utilizing pre-equalization, described according to at least one implementation of the present disclosure.

At block 1010, a determination may be made that DPD is to be used in a circumstance that includes a non-linear portion of a signal. For example, one circumstance may be when a given signal is to be broadcast in a range that invokes a power amplifier to amplify the signal to a level that causes non-linear amplification of some frequencies the signal. In these and other circumstances, a determination may be made that DPD may be advisable to counteract the non-linear amplification caused by the power amplifier.

At block 1020, pre-equalization may be performed on the signal to amplify the non-linear portion introduced by the DPD in an amount sufficient to survive the transmit filter. For example, the DPD may introduce non-linear portions of the signal at a predetermined level to offset the effect of the power amplifier. In some circumstances (such as at certain frequencies), the transmit filter may attenuate or effectively remove the non-linear portions introduced by the DPD. The pre-equalization may amplify or otherwise increase the non-linear portions of the signal introduced by the DPD in an amount generally commensurate in magnitude with the amount of attenuation caused by the transmit filer (e.g., the pre-determined DPD level). In some implementations, the pre-equalization may be frequency-dependent in a similar manner to the frequency response of the transmit filter. For example, the transmit filter may attenuate some frequencies more than others, and the pre-equalization may correspondingly amplify such frequencies in a corresponding amount. In some implementations, the pre-equalization may be implemented using a digital filter (such as an FIR or an IIR) or using analog components. In some implementations, the block 1020 may include other digital processing. For example, after pre-equalization there may be some additional digital processing before the signal is converted to analog by the DAC (which may be done separately for I and Q signals).

At block 1030, the signal may be amplified via the power amplifier. For example, after applying the DPD and the pre-equalization, the signal may undergo filtering in a transmit process and then be amplified by the power amplifier. In these and other implementations, after amplifying the signal, the signal may be amplified in a manner that the non-linear portions introduced by the DPD are counteracted and effectively reduced or removed by the non-linear performance of the power amplifier. In some implementations, the block 1030 may include other analog and/or digital processing. For example, after the DAC, the signal may be further treated by some analog baseband processing (of which the transmit filter may be the main component). After the additional analog processing, the signal may up-converted to RF by a mixing stage. The RF signal may be further amplified before being fed to a power amplifier.

At block 1040, feedback may be provided to a pre-equalizer performing the pre-equalization. For example, a low-pass transmit filter or the power amplifier itself may provide feedback to the pre-equalizer. Such feedback may include a frequency response, an output of the component, an indication of the quality of performance, an indication of a frequency response, an adjustment to frequency response to be made, a frequency output, new values for one or more parameters associated with the pre-equalizer, or any other feedback via which the pre-equalizer may adjust its operation. In some implementations, the pre-equalizer may adjust its operation based on the feedback. In some implementations, there may be some tracking functionality during the operational phase, where the DPD coefficients and/or the pre-equalization filter may be re-adjusted in response to temperature variations and/or any other variations to which updating of the DPD and/or the pre-equalization may be desirable.

At block 1050, the signal may be transmitted. For example, after the power amplification, an antenna or other broadcasting device may be used to transmit the signal.

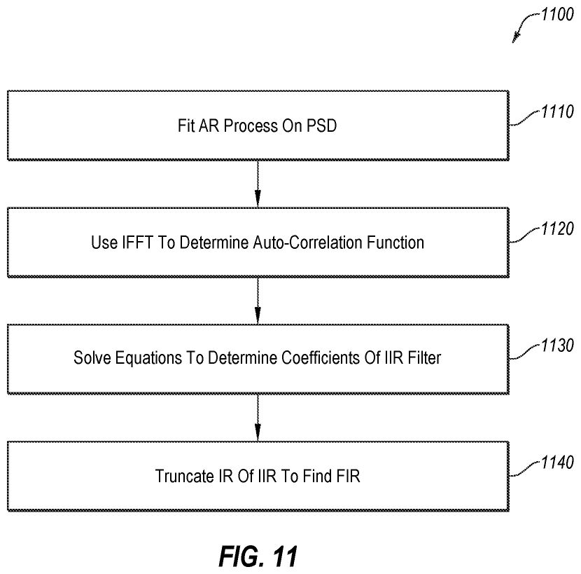

FIG. 11 illustrates a flowchart of an example method 1100 of implementing pre-equalization, described according to at least one implementation of the present disclosure.

At block 110, an autoregression (AR) process may be fit on a power spectral density (PSD) of a pre-equalizer. For example, the pre-equalizer may operate as a function of frequency, and the AR may be fit to the PSD of the pre-equalizer. In some implementations, the PSD of the pre-equalizer may be estimated based on a ratio of the frequency response of a total desired signal and a frequency response of a transmit filter.

At block 1120, an IFFT may be used to determine an auto-correlation function associated with the AR process. For example, the IFFT may be performed on the PSD of the pre-equalizer.

At block 1130, one or more equations may be solved to determine coefficients of an IIR filter. For example, solving the Yule-Walker equations in the AR process based on the IFFT may be utilized to identify or otherwise determine the coefficients of the IIR filter. In some implementations, an order of the AR process may be selected to correspond to the order of the IIR filter.

At block 1140, the impulse response (IR) of the IIR filter may be truncated to identify an FIR. For example, the IIR may be applied for a set number of instances, and the output may be utilized to generate the FIR.

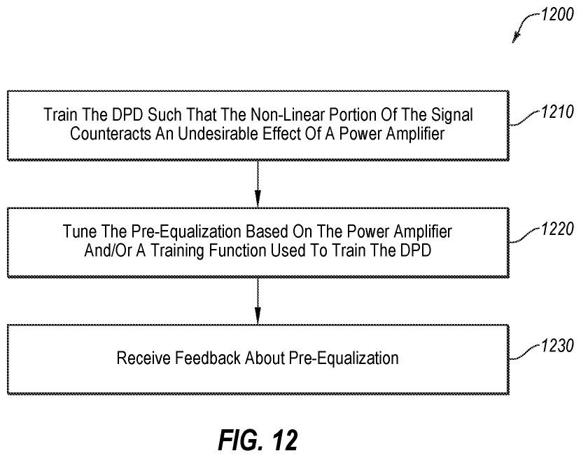

FIG. 12 illustrates a flowchart of an example method 1200 of training a system utilizing pre-equalization, described according to at least one implementation of the present disclosure.

At block 1210, the DPD may be trained such that the non-linear portion of the signal counteracts an undesirable effect of a power amplifier. For example, the DPD may be trained based on a given training signal and a frequency response observed of the power amplifier used in the transmission process. In some circumstances, the DPD may be trained using the training signal and monitored for one or more coefficients or variables to be used in a function that, when applied to a resulting received signal, results in the transmitted signal prior to the transmission process. An example of such operation is described with reference to FIG. 1A. In some implementations, such monitoring may be performed based on modeled transmissions or other theoretical implementations which are monitored without actually transmitting a signal and/or without using multiple devices actually broadcasting and/or receiving signals.

At block 1220, the pre-equalization may be tuned based on the power amplifier and/or a training function used to train the DPD. For example, the performance of the pre-equalization may be monitored for a given frequency range of amplification (e.g., the power amplifier amplifying around 5.1 GHz, 5.9 GHz, 7.1 GHz, etc.) and/or for a given training function of the DPD (e.g., training sequences or a first type or a second type, etc.) and may tune the pre-equalization based on the performance. For example, an order of an IIR filter implementing the per-equalization may be adjusted, the values of variables/coefficients of the IIR filter may be modified, a corresponding FIR filter may be identified, an exponent α may be increased or decreased, etc. In some implementations, the performance of the pre-equalization may be monitored for various combinations of levels of amplification and training functions across various tuning options such that a lookup table or database may be provided such that for a given combination of amplification and/or training function, one or more pre-selected parameters of the pre-equalization may be used to implement the pre-equalization.

At block 1230, feedback may be provided to a pre-equalizer performing the pre-equalization. For example, a low-pass transmit filter or the power amplifier itself may provide feedback to the pre-equalizer. Such feedback may include a frequency response, an output of the component, an indication of the quality of performance, an indication of a frequency response, an adjustment to frequency response to be made, a frequency output, new values for one or more parameters associated with the pre-equalizer, or any other feedback via which the pre-equalizer may adjust its operation. In some implementations, the pre-equalizer may adjust its operation based on the feedback. In some implementations, there may be a feedback path used for training (e.g., in conjunction with the block 1020) that probes the PA output signal (e.g., the output of the block 1050), may down-convert it to baseband, perform some receive filtering and/or gain, and may be sampled by an ADC to provide the received digital signal (which may include two digital received signal for I and Q).

The teachings herein are applicable to any type of wireless communication system or other digital communication systems. For example, while stations and access points are described for one context of wireless communication, the teachings of the use of pre-equalization are also applicable to other wireless communication such as Bluetooth®, Bluetooth Low Energy, Zigbee®, Thread, mmWave, etc.

One skilled in the art will appreciate that, for these and other processes and methods disclosed herein, the functions performed in the processes and methods may be implemented in differing order, simultaneously, etc. Furthermore, the outlined steps and operations are only provided as examples, and some of the steps and operations may be optional, combined into fewer steps and operations, or expanded into additional steps and operations without detracting from the essence of the disclosed implementations.

The subject technology of the present invention is illustrated, for example, according to various aspects described below. Various examples of aspects of the subject technology are described as numbered examples (1, 2, 3, etc.) for convenience. These are provided as examples and do not limit the subject technology. The aspects of the various implementations described herein may be omitted, substituted for aspects of other implementations, or combined with aspects of other implementations unless context dictates otherwise. For example, one or more aspects of example 1 below may be omitted, substituted for one or more aspects of another example (e.g., example 2) or examples, or combined with aspects of another example. The following is a non-limiting summary of some example implementations presented herein.

Example 1. A method includes performing pre-equalization of a signal for transmission, where the pre-equalization including amplifying high spectral portion of the signal corresponding to a non-linear portion of the signal based on a frequency response of a transmit filter for the non-linear portion of the signal. In such a method or system, the non-linear portion may be configured to counteract spectral spread caused by a power amplifier also to counteract in-band signal quality degradation, and the amplifying may cause the non-linear portion of the signal to survive filtering by the transmit filter such that the non-linear portion of the signal arrives at the power amplifier to counteract the spectral spread of the signal for transmission caused by the power amplifier.

Example 2. An example device includes a transmit filter configured to filter a signal prior to wireless transmission, a power amplifier configured to receive the filtered signal from the transmit filter and amplify the filtered signal prior to the wireless transmission, one or more processors, and one or more non-transitory computer-readable media storing instructions which, when executed by the one or more processors, cause the device to perform one or more operations. The operations of the example device may include performing pre-equalization of the signal prior to the signal being handled by the transmit filter, the pre-equalization configured to amplify a non-linear portion of the signal based on a frequency response of the transmit filter such that the non-linear portion of the signal survives the transmit filter and arrives at the power amplifier.

Example 3. An example non-transitory computer-readable media may store instructions which, when executed by one or more processors, cause a system to perform one or more operations. The operations may include performing pre-equalization of a signal for transmission, where the pre-equalization including amplifying a non-linear portion of the signal based on a frequency response of a transmit filter for the non-linear portion of the signal. In such a method or system, the non-linear portion may be configured to counteract spectral spread caused by a power amplifier, and the amplifying may cause the non-linear portion of the signal to survive filtering by the transmit filter such that the non-linear portion of the signal arrives at the power amplifier to counteract the spectral spread of the signal for transmission caused by the power amplifier.

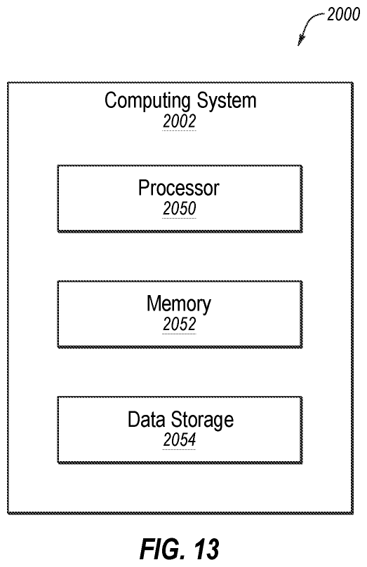

FIG. 13 illustrates a block diagram of an example computing system 2002 that may be used to perform or direct performance of one or more operations described according to at least one implementation of the present disclosure. The computing system 2002 may include a processor 2050, a memory 2052, and a data storage 2054. The processor 2050, the memory 2052, and the data storage 2054 may be communicatively coupled.

In general, the processor 2050 may include any suitable special-purpose or general-purpose computer, computing entity, or processing device including various computer hardware or software modules and may be configured to execute instructions stored on any applicable computer-readable storage media. For example, the processor 2050 may include a microprocessor, a microcontroller, a digital signal processor (DSP), an application-specific integrated circuit (ASIC), a Field-Programmable Gate Array (FPGA), or any other digital or analog circuitry configured to interpret and/or to execute computer-executable instructions and/or to process data. Although illustrated as a single processor, the processor 2050 may include any number of processors configured to, individually or collectively, perform or direct performance of any number of operations described in the present disclosure.

In some implementations, the processor 2050 may be configured to interpret and/or execute computer-executable instructions and/or process data stored in the memory 2052, the data storage 2054, or the memory 2052 and the data storage 2054. In some implementations, the processor 2050 may fetch computer-executable instructions from the data storage 2054 and load the computer-executable instructions in the memory 2052. After the computer-executable instructions are loaded into memory 2052, the processor 2050 may execute the computer-executable instructions.

The memory 2052 and the data storage 2054 may include computer-readable storage media for carrying or having computer-executable instructions or data structures stored thereon. Such computer-readable storage media may include any available media that may be accessed by a general-purpose or special-purpose computer, such as the processor 2050. By way of example, and not limitation, such computer-readable storage media may include tangible or non-transitory computer-readable storage media including Random Access Memory (RAM), Read-Only Memory (ROM), Electrically Erasable Programmable Read-Only Memory (EEPROM), Compact Disc Read-Only Memory (CD-ROM) or other optical disk storage, magnetic disk storage or other magnetic storage devices, flash memory devices (e.g., solid state memory devices), or any other storage medium which may be used to carry or store particular program code in the form of computer-executable instructions or data structures and which may be accessed by a general-purpose or special-purpose computer. Combinations of the above may also be included within the scope of computer-readable storage media. Computer-executable instructions may include, for example, instructions and data configured to cause the processor 2050 to perform a certain operation or group of operations.

Some portions of the detailed description refer to different modules configured to perform operations. One or more of the modules may include code and routines configured to enable a computing system to perform one or more of the operations described therewith. Additionally or alternatively, one or more of the modules may be implemented using hardware including any number of processors, microprocessors (e.g., to perform or control performance of one or more operations), DSP's, FPGAs, ASICs or any suitable combination of two or more thereof. Alternatively or additionally, one or more of the modules may be implemented using a combination of hardware and software. In the present disclosure, operations described as being performed by a particular module may include operations that the particular module may direct a corresponding system (e.g., a corresponding computing system) to perform. Further, the delineating between the different modules is to facilitate explanation of concepts described in the present disclosure and is not limiting. Further, one or more of the modules may be configured to perform more, fewer, and/or different operations than those described such that the modules may be combined or delineated differently than as described.

Some portions of the detailed description are presented in terms of algorithms and symbolic representations of operations within a computer. These algorithmic descriptions and symbolic representations are the means used by those skilled in the data processing arts to convey the essence of their innovations to others skilled in the art. An algorithm is a series of configured operations leading to a desired end state or result. In example implementations, the operations carried out require physical manipulations of tangible quantities for achieving a tangible result.

Unless specifically stated otherwise, as apparent from the discussion, it is appreciated that throughout the description, discussions utilizing terms such as detecting, determining, analyzing, identifying, scanning or the like, can include the actions and processes of a computer system or other information processing device that manipulates and transforms data represented as physical (electronic) quantities within the computer system's registers and memories into other data similarly represented as physical quantities within the computer system's memories or registers or other information storage, transmission or display devices.

Example implementations may also relate to an apparatus for performing the operations herein. This apparatus may be specially constructed for the required purposes, or it may include one or more general-purpose computers selectively activated or reconfigured by one or more computer programs. Such computer programs may be stored in a computer readable medium, such as a computer-readable storage medium or a computer-readable signal medium. Computer-executable instructions may include, for example, instructions and data which cause a general-purpose computer, special-purpose computer, or special-purpose processing device (e.g., one or more processors) to perform or control performance of a certain function or group of functions.

Although the subject matter has been described in language specific to structural features and/or methodological acts, it is to be understood that the subject matter configured in the appended claims is not necessarily limited to the specific features or acts described above. Rather, the specific features and acts described above are disclosed as example forms of implementing the claims.

An example apparatus can include a Wireless Access Point (WAP) or a station and incorporating a VLSI processor and program code to support. An example transceiver couples via an integral modem to one of a cable, fiber or digital subscriber backbone connection to the Internet to support wireless communications, e.g., IEEE 802.11 compliant communications, on a Wireless Local Area Network (WLAN). The WiFi stage includes a baseband stage, and the analog front end (AFE) and Radio Frequency (RF) stages. In the baseband portion wireless communications transmitted to or received from each user/client/station are processed. The AFE and RF portion handles the up-conversion on each of transmit paths of wireless transmissions initiated in the baseband. The RF portion also handles the down-conversion of the signals received on the receive paths and passes them for further processing to the baseband.

An example apparatus can be a multiple-input multiple-output (MIMO) apparatus supporting as many as N×N discrete communication streams over N antennas. In an example the MIMO apparatus signal processing units can be implemented as N×N. In various implementations, the value of N can be 4, 6, 8, 12, 16, etc. Extended MIMO operation enables the use of up to 2N antennae in communication with another similarly equipped wireless system. It should be noted that extended MIMO systems can communicate with other wireless systems even if the systems do not have the same number of antennae, but some of the antennae of one of the stations might not be utilized, reducing optimal performance.

Channel State Information (CSI) from any of the devices described herein can be extracted independent of changes related to channel state parameters and used for spatial diagnosis services of the network such as motion detection, proximity detection, and localization which can be utilized in, for example, WLAN diagnosis, home security, health care monitoring, smart home utility control, elder care, automotive tracking and monitoring, home or mobile entertainment, automotive infotainment, and the like.

Unless specific arrangements described herein are mutually exclusive with one another, the various implementations described herein can be combined in whole or in part to enhance system functionality and/or to produce complementary functions. Likewise, aspects of the implementations may be implemented in standalone arrangements. Thus, the above description has been given by way of example only and modification in detail may be made within the scope of the present invention.

With respect to the use of substantially any plural or singular terms herein, those having skill in the art can translate from the plural to the singular or from the singular to the plural as is appropriate to the context or application. The various singular/plural permutations may be expressly set forth herein for sake of clarity. A reference to an element in the singular is not intended to mean “one and only one” unless specifically stated, but rather “one or more.” Moreover, nothing disclosed herein is intended to be dedicated to the public regardless of whether such disclosure is explicitly recited in the above description.

In general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). Furthermore, in those instances where a convention analogous to “at least one of A, B, and C, etc.” is used, in general, such a construction is intended in the sense one having skill in the art would understand the convention (e.g., “a system having at least one of A, B, and C” would include but not be limited to systems that include A alone, B alone, C alone, A and B together, A and C together, B and C together, or A, B, and C together, etc.). Also, a phrase presenting two or more alternative terms, whether in the description, claims, or drawings, should be understood to include one of the terms, either of the terms, or both terms. For example, the phrase “A or B” will be understood to include the possibilities of “A” or “B” or “A and B.”

Additionally, the use of the terms “first,” “second,” “third,” etc., are not necessarily used herein to connote a specific order or number of elements. Generally, the terms “first,” “second,” “third,” etc., are used to distinguish between different elements as generic identifiers. Absence a showing that the terms “first,” “second,” “third,” etc., connote a specific order, these terms should not be understood to connote a specific order. Furthermore, absence a showing that the terms first,” “second,” “third,” etc., connote a specific number of elements, these terms should not be understood to connote a specific number of elements.

The present invention may be embodied in other specific forms without departing from its spirit or essential characteristics. The described implementations are to be considered in all respects only as illustrative and not restrictive. The scope of the invention is, therefore, indicated by the appended claims rather than by the foregoing description. All changes which come within the meaning and range of equivalency of the claims are to be embraced within their scope.

1. A method comprising:
performing pre-equalization of a signal for transmission, the pre-equalization including amplifying intentional distortion of the signal, the amplification based on a ratio of a total desired frequency response to a frequency response of a low-pass transmit filter corresponding to a spectral mask imposed by a regulatory body,
wherein the intentional distortion is configured to counteract non-linear behavior of a power amplifier, and
wherein the amplifying causes the intentional distortion of the signal to survive filtering by the low-pass transmit filter and arrives at the power amplifier to counteract the non-linear behavior of the power amplifier.

2. The method of claim 1, wherein the intentional distortion of the signal corresponds to a digital pre-distortion (DPD) introduced to counteract the non-linear behavior of the power amplifier.

3. The method of claim 2, wherein an amount of amplification of the pre-equalization results in the intentional distortion of the signal after the transmit filter being at a predetermined DPD level.

4. The method of claim 2, wherein a frequency response of the pre-equalization is configurable using one or more parameters.

5. The method of claim 4, further comprising:
receiving feedback regarding performance of the pre-equalization; and
adjusting the one or more parameters of the pre-equalization based on the feedback.

6. The method of claim 5, wherein the feedback is received from the transmit filter.

7. The method of claim 1, wherein the pre-equalization is implemented using one of an infinite impulse response (IIR) filter or a finite impulse response (FIR) filter.

8. The method of claim 1, wherein the pre-equalization is performed using one or more analog components.

9. The method of claim 1, wherein the pre-equalization is performed in a digital domain and the transmit filter and the power amplifier operate in an analog domain.

10. The method of claim 1, further comprising:
transmitting a previous signal at a first transmission power prior to performing the pre-equalization; and
in conjunction with performing the pre-equalization, transmitting the signal at a second transmission power higher than the first transmission power.

11. The method of claim 1, further comprising:
transmitting a previous signal at a first transmission power prior to performing the pre-equalization; and
in conjunction with performing the pre-equalization, transmitting the signal at or below the first transmission power and at a higher bit rate than the previous signal.

12. A device comprising:
a transmit filter configured to filter a signal prior to wireless transmission and corresponding to a spectral mask imposed by a regulatory body;
a power amplifier configured to receive the filtered signal from the transmit filter and amplify the filtered signal prior to the wireless transmission;
one or more processors; and
one or more non-transitory computer-readable media storing instructions which, when executed by the one or more processors, cause the device to perform one or more operations, the operations comprising:
performing pre-equalization of the signal prior to the signal being handled by the transmit filter, the pre-equalization configured to amplify intentional distortion of the signal, the amplification based on a ratio of a total desired frequency response to a frequency response of the transmit filter such that the intentional distortion of the signal survives the transmit filter and arrives at the power amplifier.

13. The device of claim 12, wherein the intentional distortion of the signal corresponds to a digital pre-distortion (DPD) introduced to counteract non-linear behavior of the power amplifier.

14. The device of claim 13, wherein an amount of amplification of the pre-equalization results in the intentional distortion of the signal after the transmit filter being at a predetermined DPD level.

15. The device of claim 12, wherein a frequency response of the pre-equalization is configurable using one or more parameters.

16. The device of claim 15, the operations further comprising:
receiving feedback regarding performance of the pre-equalization from the transmit filter; and
adjusting the one or more parameters of the pre-equalization based on the feedback.

17. The device of claim 12, further comprising at least one of an infinite impulse response (IIR) filter or a finite impulse response (FIR) filter, wherein the pre-equalization is implemented using the IIR filter or the FIR filter.

18. The device of claim 12, wherein the pre-equalization is performed in a digital domain and the transmit filter and the power amplifier operate in an analog domain.

19. The device of claim 12, the operations further comprising:
transmitting a previous signal at a first transmission power prior to performing the pre-equalization; and
in conjunction with performing the pre-equalization, transmitting the signal at a second transmission power higher than the first transmission power.

20. One or one or more non-transitory computer-readable media storing instructions which, when executed by one or more processors, cause a system to perform one or more operations, the operations comprising:
performing pre-equalization of a signal for transmission, the pre-equalization including amplifying intentional distortion of the signal, the amplification based on a ratio of a total desired frequency response to a frequency response of a low-pass transmit filter corresponding to a spectral mask imposed by a regulatory body,
wherein the intentional distortion is configured to counteract non-linear behavior of a power amplifier, and
wherein the amplifying causes the intentional distortion of the signal to survive filtering by the low-pass transmit filter and arrive at the power amplifier to counteract the non-linear behavior of the power amplifier.

21. The method of claim 1, wherein the total desired frequency response includes the signal for transmission after treatment of both the low-pass transmit filter and the pre-equalization at a plurality of frequencies.

22. The method of claim 21, wherein an absolute value of the total desired frequency response is tuned using an exponent α and where the absolute value of the total desired frequency response (H_{Total}(ƒ)) is determined by

|H_{Total}(ƒ)|=|sinc(ƒ/ƒₛ)|^{α}
where |sinc(ƒ/ƒₛ)| represents an absolute value of the sinc function
$$( \frac{sin ( x )}{x} )$$
operating on a ratio of a given frequency (ƒ) and a sampling rate of the frequency (ƒₛ).

23. The method of claim 1, wherein:
the spectral mask imposed by a regulatory body includes limitations on transmit signal strength in one or more bands of frequencies at which parties are not permitted to transmit, and
the regulatory body includes at least one of Federal Communications Commission (FCC), Institute of Electrical and Electronics Engineers (IEEE), or Body of European Regulators for Electronic Communications (BEREC).

24. The device of claim 12, wherein the transmit filter includes a low-pass filter.
